(19) United States
(12) Patent Application Publication
(10) Pub. No.: US 2016/0312964 A1
(43) Pub. Date: Oct. 27, 2016

(54) Surface Emitting Unit

(71) Applicant: KONICA MINOLTA, INC., Tokyo (JP)

(72) Inventors: Yusuke HIRAO, Takatsuki-shi (JP); Koujirou SEKINE, Ibaraki-shi (JP); Kou OSAWA, Amagasaki-shi (JP)

(21) Appl. No.: 15/102,206

(22) PCT Filed: Nov. 6, 2014
(86) PCT No.: PCT/JP2014/079478

§ 371 Date: Jun. 6, 2016

(30) Foreign Application Priority Data
Dec. 6, 2013 (JP) 2013-253296

(51) Int. Cl. F21V 1/00; H01L 27/32; F21V 7/22; H01L 51/52

(52) U.S. Cl. CPC F21K 9/61; F21V 7/22; H01L 51/5268; H01L 27/3293; H01L 51/5271; F21Y 2105/00

(57) ABSTRACT

A surface-emitting unit includes a surface-emitting panel which emits light, a transmissive member which is arranged to face a light-emitting surface and propagates light emitted from the surface-emitting panel, and a reflection member which scatters propagated light. The light-emitting surface has a light-emitting region and a non-light-emitting region. The reflection member is provided on the surface-emitting panel so as to overlap with the non-light-emitting region. When a light distribution curve in a plane perpendicular to the light-emitting surface is drawn for each surface-emitting panel, the light distribution curve has at least a portion in which a condition of L>cos θ is satisfied, with a luminance on a front side along an axis extending in a direction of normal to the light-emitting surface being defined as 1 and L representing a luminance in a direction in which an angle formed with respect to the axis in the plane is θ.

### TECHNICAL FIELD

The present disclosure relates to a surface-emitting unit and particularly to a surface-emitting unit including a plurality of surface-emitting panels disposed such that light-emitting surfaces are two-dimensionally aligned.

### BACKGROUND ART

A surface-emitting unit including a surface-emitting panel as a light source has recently attracted attention. The surface-emitting unit is not limited to a lighting apparatus but used also for a backlight for a liquid crystal display, a computer monitor, or an outdoor advertisement such as a digital signage. In general, a surface-emitting element such as an organic electroluminescence (EL) element is used for the surface-emitting panel. The organic EL element can obtain a high luminance with low power consumption, and exhibits excellent performance also in terms of responsiveness and lifetime.

Since it is necessary to seal a surface-emitting element and connect a line to a surface-emitting element in a surface-emitting panel, a non-light-emitting region is located around an outer edge of a light-emitting surface of the surface-emitting panel. In order to achieve a large area of a light source with a small number of panels, arrangement of surface-emitting panels without contact with each other is preferred. In that case, a gap is produced between surface-emitting panels and this gap is also a site not emitting light.

Therefore, in a surface-emitting unit including a plurality of surface-emitting panels, lowering in luminance in a front direction in a portion corresponding to a non-light-emitting portion and a periphery thereof is inevitable. Therefore, without any measures being taken, such lowering in luminance appears as variation in luminance and a dark portion may be produced along the non-light-emitting portion.

Japanese Laid-Open Patent Publication No. 2005-353564 (PTD 1) discloses the invention relating to a lighting apparatus. This lighting apparatus includes a surface-emitting device and an optical member. This publication states that recognition of a dark portion caused by a non-light-emitting portion is less likely according to this lighting apparatus.

Japanese Laid-Open Patent Publication No. 2005-158369 (PTD 2) discloses the invention relating to a lighting apparatus. This lighting apparatus includes an optical member and a plurality of light-emitting elements. This publication states that illumination light can be emitted with less variation in luminance over a wide area from a front surface of each light-emitting element by using the plurality of light-emitting elements with this optical member and the lighting apparatus.

### CITATION LIST

### Patent Document

PTD 1: Japanese Laid-Open Patent Publication No. 2005-353564
PTD 2: Japanese Laid-Open Patent Publication No. 2005-158369

### SUMMARY OF INVENTION

### Technical Problem

An object of the present disclosure is to provide a surface-emitting unit achieving improvement in luminance in a front direction in a portion corresponding to a non-light-emitting portion and a periphery thereof.

### Solution to Problem

A surface-emitting unit according to one embodiment of the present disclosure includes a plurality of surface-emitting panels which are disposed such that light-emitting surfaces are two-dimensionally aligned and emit light toward a front, a transmissive member which is arranged to face the light-emitting surfaces of adjacent surface-emitting panels and propagates light emitted from the surface-emitting panels as being reflected therein, and a light scattering portion which scatters the light propagated by the transmissive member toward the front.

The light-emitting surface of each of the plurality of surface-emitting panels has a light-emitting region which emits light and a non-light-emitting region which is located around an outer periphery of the light-emitting region and does not emit light. The light scattering portion is provided on the surface-emitting panel so as to overlap with the non-light-emitting region when viewed from the front. When a light distribution curve in a plane perpendicular to the light-emitting surface of light emitted from the surface-emitting panel is drawn for each of the plurality of surface-emitting panels, the surface-emitting unit has at least a portion where the light distribution curve satisfies a condition of L>cos θ, with a luminance on a front side along an axis extending in a direction of normal to the light-emitting surface being defined as 1 and L representing a luminance in a direction in which an angle formed with respect to the axis in the plane is θ.

### BRIEF DESCRIPTION OF DRAWINGS

FIG. 1 is a plan view showing a surface-emitting unit according to a first embodiment.

FIG. 2 is a schematic cross-sectional view along the line II-II shown in FIG. 1.

FIG. 3 is a perspective view showing a surface-emitting panel, a transmissive member, and a reflection member included in the surface-emitting unit according to the first embodiment.

FIG. 4 is a cross-sectional view showing an organic EL element provided in the surface-emitting panel according to the first embodiment.

FIG. 5 is a diagram showing light distributions in a vertical plane according to a first configuration example to a third configuration example of the organic EL element provided in the surface-emitting panel shown in FIG. 1.

FIG. 6 is a chart showing exemplary conditions for specific film configurations implementing the organic EL elements according to the first configuration example to the third configuration example.

FIG. 7 is a cross-sectional view showing a surface-emitting unit in a second embodiment.

FIG. 8 is a graph showing a standardized front luminance profile of surface-emitting units according to Examples 1 to 4 and a Comparative Example.

FIG. 9 is a conceptual, partially enlarged view showing a distribution of a density of dimming patterns of an optical filter in Example 4.

FIG. 10 shows a density profile in a cross-section along the line X-X in FIG. 9.

FIG. 11 is a cross-sectional view showing a surface-emitting unit in another embodiment.

### DESCRIPTION OF EMBODIMENTS

Each embodiment and each example based on the present invention will be described hereinafter with reference to the drawings. When the number and an amount are mentioned in the description of each embodiment and each example, the scope of the present invention is not necessarily limited to the number and the amount unless otherwise specified. In the description of each embodiment and each example, the same and corresponding elements have the same reference numeral allotted and redundant description may not be repeated.

### First Embodiment

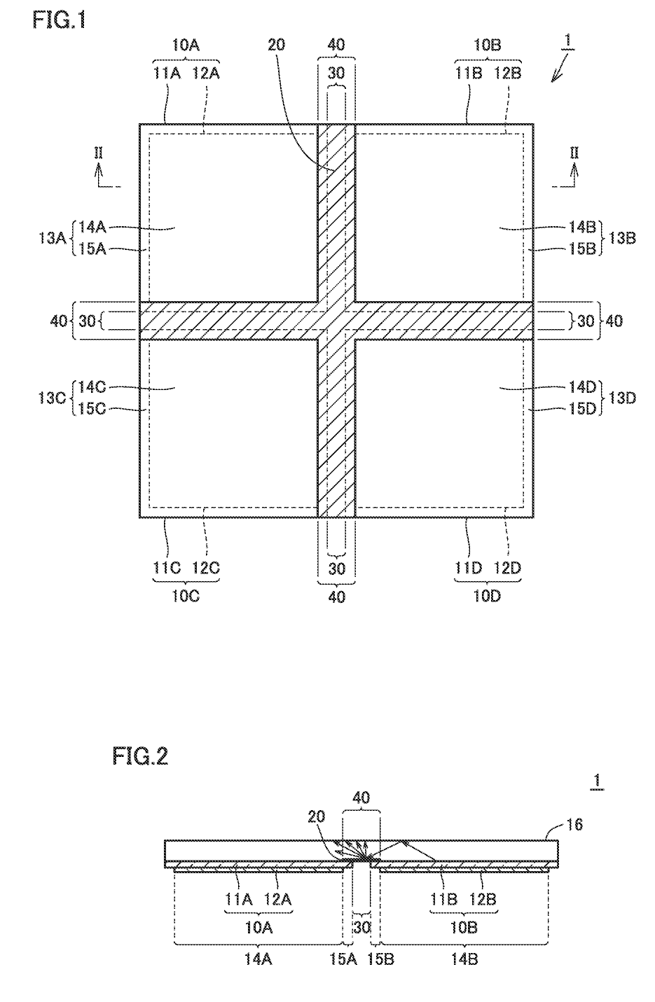

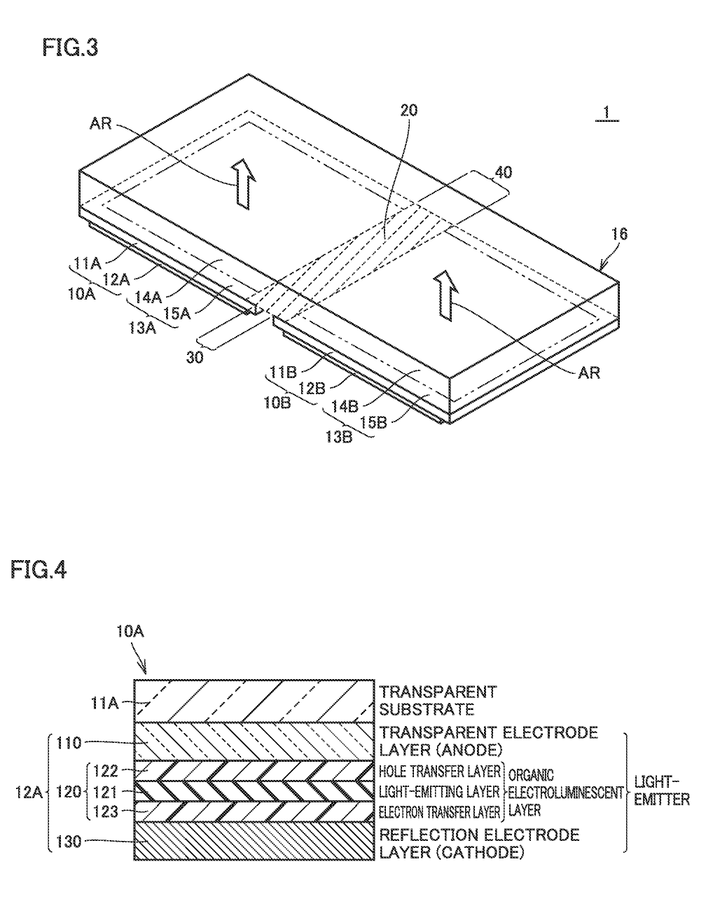

A surface-emitting unit 1 according to a first embodiment will be described with reference to FIGS. 1 to 6. FIG. 1 is a plan view showing surface-emitting unit 1. FIG. 1 shows surface-emitting unit 1 from which a transmissive member 16 which will be described later having been removed. FIG. 2 is a schematic cross-sectional view of the surface-emitting unit shown in FIG. 1 along the line II-II shown in FIG. 1. FIG. 3 is a perspective view showing surface-emitting panels 10A and 10B, transmissive member 16, and a reflection member 20 included in surface-emitting unit 1.

(Surface-Emitting Unit 1)

As shown in FIGS. 1 to 3, surface-emitting unit 1 generally has an outer shape substantially in a form of a flat parallelepiped. Surface-emitting unit 1 includes surface-emitting panels 10A to 10D, transmissive member 16, and reflection member 20.

Surface-emitting unit 1 may include a base plate and a frame plate (not shown) as a housing for accommodating surface-emitting panels 10A to 10D, transmissive member 16, and reflection member 20. The base plate is a member for forming a rear surface of the housing and holding surface-emitting panels 10A to 10D, and the frame plate is a member forming side surfaces of the housing and arranged along an outer periphery of surface-emitting unit 1.

(Surface-Emitting Panels 10A to 10D)

Each of surface-emitting panels 10A to 10D has a shape of a flat plate which extends along a surface direction. Surface-emitting panels 10A to 10D are disposed such that light-emitting surfaces 13A to 13D are two-dimensionally aligned. Surface-emitting panels 10A to 10D are formed of a stack of respective transparent substrates 11A to 11D and respective light-emitters 12A to 12D including organic EL elements, and transparent substrates 11A to 11D are located on a side of transmissive member 16. Surface-emitting panels 10A to 10D thus constructed are surface-emitting panels each constituted of organic EL elements of what is called a bottom emission type.

Surface-emitting panels 10A to 10D are not limited to those as above, and they may each be formed from a surface-emitting panel constituted of organic EL elements of a top emission type, a surface-emitting panel constituted of a plurality of light-emitting diodes and a diffusion plate arranged on an exit surface side (a front side) of each of the plurality of light-emitting diodes, or a surface-emitting panel including a cold cathode-ray tube.

Surface-emitting panels 10A to 10D are arranged in array. Surface-emitting panels 10A to 10D are arranged at a distance from one another and a gap 30 is provided between adjacent surface-emitting panels. Four gaps 30 in total are provided between adjacent surface-emitting panels of surface-emitting panels 10A to 10D.

By providing gap 30, a light source can be larger in area with a smaller number of panels than surface-emitting panels 10A to 10D arranged as being in contact with one another. When a light source does not have to be large in area in particular, surface-emitting panels 10A to 10D may be arranged as being in contact with one another without providing gap 30.

Surface-emitting panels 10A to 10D have light-emitting surfaces 13A to 13D, respectively. Light-emitting surfaces 13A to 13D are formed from respective outer surfaces of transparent substrates 11A to 11D located opposite to a side where light-emitters 12A to 12D are located. Light generated by light-emitters 12A to 12D passes through transparent substrates 11A to 11D and is emitted toward transmissive member 16 (toward the front) (see an arrow AR shown in FIG. 3) through light-emitting surfaces 13A to 13D.

As described above, surface-emitting panels 10A to 10D are disposed such that light-emitting surfaces 13A to 13D are two-dimensionally aligned. Surface-emitting panels 10A to 10D according to the present embodiment are disposed such that light-emitting surfaces 13A to 13D are flush with one another.

Light-emitting surfaces 13A to 13D have light-emitting regions 14A to 14D which emit light and non-light-emitting regions 15A to 15D which are located around outer peripheries of light-emitting regions 14A to 14D, respectively. Light-emitting regions 14A to 14D each have a rectangular shape. Non-light-emitting regions 15A to 15D are in a form of a rectangular frame. Non-light-emitting regions 15A to 15D are formed by providing a site for sealing of organic EL elements included in light-emitters 12A to 12D or connection of a line to an organic EL element.

In surface-emitting unit 1, a portion including gap 30 provided between adjacent surface-emitting panels and the non-light-emitting region of the surface-emitting panel located adjacently to gap 30 implements a non-light-emitting portion 40. Non-light-emitting portion 40 is a site which will cause a dark portion when no measures are taken, and four non-light-emitting portions in total are formed between adjacent surface-emitting panels. When no gap 30 is provided, a non-light-emitting region between adjacent surface-emitting panels corresponds to non-light-emitting portion 40.

FIG. 4 is a cross-sectional view showing an organic EL element provided in surface-emitting panel 10A. FIG. 4 does not show transmissive member 16 provided on light-emitting surface 13A for the sake of convenience. A configuration of an organic EL element provided in surface-emitting panels 10A to 10D will be described with reference to FIG. 4. Since surface-emitting panels 10A to 10D are identical in configuration to one another, description will be given below with surface-emitting panel 10A being focused on.

An organic EL element provided in surface-emitting panel 10A includes, in addition to transparent substrate 11A, a transparent electrode layer 110, an organic electroluminescent layer 120, and a reflection electrode layer 130 as light-emitter 12A. Transparent electrode layer 110, organic electroluminescent layer 120, and reflection electrode layer 130 are stacked on a main surface of transparent substrate 11A in this order. Transparent electrode layer 110 corresponds to an anode and reflection electrode layer 130 corresponds to a cathode.

Transparent substrate 11A serves as a base material having a main surface (a surface opposite to light-emitting surface 13A), on which various layers described above are formed, and it is formed from an insulating member which satisfactorily allows passage of light in a visible light region. Transparent substrate 11A may be a rigid or flexible substrate. From a point of view of passage of light described above, for example, a glass plate, a plastic plate, a high-polymer film, a silicon plate, or a stack plate of the former implements transparent substrate 11A.

Transparent electrode layer 110 is provided on one main surface (the surface opposite to light-emitting surface 13A) of transparent substrate 11A, and formed from a film which allows satisfactory passage of light in the visible light region and has satisfactory electrical conductivity.

Specifically, transparent electrode layer 110 is formed, for example, from an inorganic conductive film such as an ITO (a mixture of an indium oxide and a tin oxide) film, an IZO (a mixture of an indium oxide and a zinc oxide film) film, a ZnO film, a CuI film, and an SnO2 film, an organic conductive film such as a PEDOT/PSS (a mixture of polyethylenedioxythiophene and polystyrenesulfonate) film, or a composite conductive film obtained by dispersing silver nanowires or carbon nanotubes in a high-polymer material.

Transparent electrode layer 110 is provided on transparent substrate 11A by adopting, for example, any of vapor deposition, spin coating, casting, ink-jet printing, and printing. In particular, spin coating, ink-jet printing, and printing can particularly suitably be made use of because an even film is likely to be obtained and generation of pinholes can be suppressed.

Organic electroluminescent layer 120 is provided on a main surface of transparent electrode layer 110 opposite to a side where transparent substrate 11A is located, includes a light-emitting layer 121 composed of at least a fluorescent compound or a phosphorescent compound, and is formed from a film which allows satisfactory passage of light in the visible light region. Organic electroluminescent layer 120 further has a hole transfer layer 122 located on a side of transparent electrode layer 110 relative to light-emitting layer 121 and an electron transfer layer 123 located on a side of reflection electrode layer 130 relative to light-emitting layer 121. A lithium fluoride film or an inorganic metal salt film may be formed at any position in organic electroluminescent layer 120 in a direction of thickness thereof.

For example, a stack film of an organic material represented, for example, by Alq3 (tris(8-hydroxyquinolinato)aluminum) or α-NPD (4,4′-bis[N-(1-naphtyl)-N-phenylamino]biphenyl) and a stack film including a film formed of such an organic material and a film of a metal represented by an MgAg alloy can suitably be made use of for organic electroluminescent layer 120.

An organic metal complex may be employed for a material for organic electroluminescent layer 120, from a point of view of improvement in external quantum efficiency or longer emission lifetime of an organic EL element. Here, as a metal element in accordance with formation of a complex, any one metal belonging to a group VIII, a group IX, and a group X in the periodic table, or Al or Zn is preferred and in particular, Ir, Pt, Al, or Zn is preferred.

Organic electroluminescent layer 120 is provided on transparent electrode layer 110 by adopting, for example, any of vapor deposition, spin coating, casting, ink-jet printing, and printing. In particular, spin coating, ink-jet printing, and printing can particularly suitably be made use of because an even film is likely to be obtained and generation of pinholes can be suppressed.

Reflection electrode layer 130 is provided on a main surface of organic electroluminescent layer 120 opposite to the side where transparent electrode layer 110 is located, and formed from a film which satisfactorily reflects light in the visible light region and has satisfactory electrical conductivity. Specifically, reflection electrode layer 130 is formed from a metal film composed, for example, of Al, Ag, Ni, Ti, Na, or Ca, or an alloy containing any of them. Reflection electrode layer 130 is provided on organic electroluminescent layer 120, for example, by adopting vapor deposition or sputtering.

(Transmissive Member 16)

Referring again to FIGS. 2 and 3, transmissive member 16 is arranged to face light-emitting surfaces 13A to 13D of respective surface-emitting panels 10A to 10D and located on the front side when viewed from transparent substrates 11A to 11D. Transmissive member 16 according to the present embodiment is provided on surface-emitting panels 10A to 10D across gap 30. Transmissive member 16 is fixed to transparent substrates 11A to 11D (light-emitting surfaces 13A to 13D) with an optically transparent adhesive (not shown).

A material which is high in transmittance (of which total luminous transmittance in a range of wavelengths of visible light measured with a method in conformity with JIS K 7361-1: 1997 is, for example, not lower than 80%) and is excellent in flexibility is preferably used for transmissive member 16. A substrate made of a resin having transparency such as an acrylic resin or a film of a transparent resin such as polyethylene terephthalate (PET) is exemplified as transmissive member 16.

In the present embodiment, transmissive member 16 and transparent substrates 11A to 11D are formed as members separate from one another. Light-emitters 12A to 12D function as light-emitting portions, and transmissive member 16 and transparent substrates 11A to 11D function as light guide portions which guide light generated by light-emitters 12A to 12D.

Light generated by light-emitters 12A to 12D passes through transparent substrates 11A to 11D, is emitted from light-emitting surfaces 13A to 13D, and thereafter enters transmissive member 16. The light which enters the transmissive member passes through transmissive member 16, and exits as it is or exits as being reflected and propagated in transmissive member 16.

(Reflection Member 20)

Reflection member 20 has a function as a light scattering portion, and scatters and reflects some of light emitted from light-emitting surfaces 13A to 13D of respective surface-emitting panels 10A to 10D and propagated in transmissive member 16. Reflection member 20 is formed from a cross-shaped member (see FIG. 1) having four sites in total in correspondence with four non-light-emitting portions 40 (see FIG. 1), each of which extends in a form of a rod from a central portion of surface-emitting unit 1. A reflection member which scatters and reflects light without allowing passage thereof is preferred as reflection member 20.

Each of the sites of reflection member 20 which extends in a form of a rod is arranged along outer edges of light-emitting surfaces of adjacent surface-emitting panels so as to overlap with a non-light-emitting region when viewed from the front (the light-emitting surface). More specifically, reflection member 20 is provided on light-emitting surfaces of surface-emitting panels so as to lie across outer edges of the light-emitting surfaces of the adjacent surface-emitting panels and to extend along the outer edges.

Reflection member 20 will be described in further detail with reference to FIGS. 2 and 3. Since the four sites of reflection member 20 which extend in a form of a rod are identical in shape to one another, description will be given below with attention being paid only to a portion of surface-emitting panels 10A to 10D described above between surface-emitting panel 10A and surface-emitting panel 10B.

As shown in FIGS. 2 and 3, reflection member 20 is located on light-emitting surface 13A of first surface-emitting panel 10A and light-emitting surface 13B of second surface-emitting panel 10B so as to face non-light-emitting portion 40.

More specifically, reflection member 20 is provided on first surface-emitting panel 10A and second surface-emitting panel 10B so as to lie across non-light-emitting region 15A located along the outer edge of light-emitting surface 13A of first surface-emitting panel 10A on a side of second surface-emitting panel 10B and non-light-emitting region 15B located along the outer edge of light-emitting surface 13B of second surface-emitting panel 10B on a side of first surface-emitting panel 10A (that is, reflection member 20 overlaps with non-light-emitting regions 15A and 15B of such portions when viewed from the front) and to extend along non-light-emitting regions 15A and 15B.

A method of providing a scattering function of reflection member 20 includes a method of roughening of a surface of transmissive member 16 in advance, a method of roughening a surface of reflection member 20, and a method of providing on a smooth reflective metal film, a scattering layer in which particles for scattering have been mixed in a resin binder. Reflection member 20 may be formed from a white ink based on an organic solvent in which scattering particles have been dispersed. In this case, a scattering and reflecting surface of reflection member 20 can be formed, for example, by applying a white ink with ink-jet printing to the surface of transmissive member 16.

(Light Distribution in Vertical Plane)

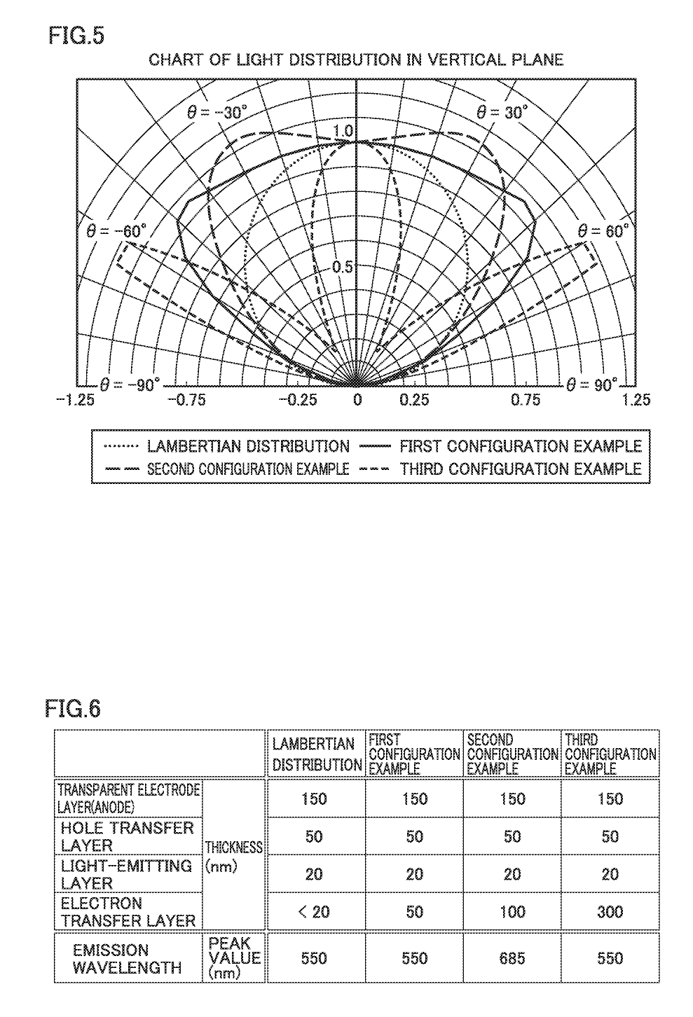

FIG. 5 is a diagram showing light distributions in a vertical plane according to a first configuration example to a third configuration example of the organic EL element provided in the surface-emitting panel shown in FIG. 1. FIG. 6 is a chart showing exemplary conditions for specific film configurations implementing the organic EL elements according to the first configuration example to the third configuration example. The first configuration example to the third configuration example of the organic EL element provided in the surface-emitting panel of the surface-emitting unit according to the present embodiment will be described in detail with reference to FIGS. 5 and 6.

As shown in FIG. 5, when a light distribution curve in a plane perpendicular to a light-emitting surface of light emitted from a surface-emitting panel is drawn, the organic EL elements according to the first configuration example to the third configuration example include a portion where the light distribution curve satisfies a condition of L>cos θ, with a luminance on the front side along a reference axis (also called an optical axis herein) extending in a direction of normal to the light-emitting surface (that is, a luminance at θ=0° shown in the figure) being defined as 1 and L representing a luminance in a direction in which an angle formed with respect to the optical axis in the plane is θ (that is, a luminance in a range of −90°<θ<90° where) θ≠0°).

Namely, the organic EL element according to the first configuration example satisfies the condition of L>cos θ substantially in a range of −70°≦θ≦70° (θ≠0°), the organic EL element according to the second configuration example satisfies the condition of L>cos θ substantially in a range of −65°≦θ≦65° (θ≠0°), and the organic EL element according to the third configuration example satisfies the condition of L>cos θ substantially in a range of −80°<θ≦50° and 50°<θ<80°.

FIG. 5 shows for comparison, a Lambertian distribution which is a light distribution in the vertical plane of a normal organic EL element (the Lambertian distribution satisfying a condition of L=cos θ=1 in the range of −90°<θ<90°).

Here, the organic EL elements according to the first configuration example to the third configuration example having the light distributions in the vertical plane described above can be realized, for example, by adjusting a thickness of the electron transfer layer as shown in FIG. 6.

The Lambertian distribution is substantially obtained by employing an ITO film for the transparent electrode layer, employing an MgAg film for the electron transfer layer, employing an Alq3 film for the light-emitting layer, employing an α-NPD film for the hole transfer layer, employing an Ag film for the reflection electrode layer, and setting a thickness of the electron transfer layer to 20 nm or smaller when thicknesses of the transparent electrode layer/the hole transfer layer/the light-emitting layer are set to 150 nm/50 nm/20 nm, respectively, as shown in FIG. 6.

By setting a thickness of the electron transfer layer to 50 nm, the light distribution in the vertical plane in the first configuration example is obtained. By setting a thickness of the electron transfer layer to 100 nm, the light distribution in the vertical plane in the second configuration example is obtained. By setting a thickness of the electron transfer layer to 300 nm, the light distribution in the vertical plane in the third configuration example is obtained.

FIG. 6 also shows for the reference purpose, a peak value of a wavelength of light emitted from the organic EL element when such a film configuration is adopted.

The light distributions in the vertical plane of the organic EL elements according to the first configuration example to the third configuration example mean that angular dependency of light which exits from the light-emitting surface is different from the Lambertian distribution of a normal light source, and particularly mean that a quantity of light which exits in an oblique direction on the front side is greater than a quantity of light which exits toward the front.

Therefore, by employing the surface-emitting panel provided with the organic EL element having such a light distribution in the vertical plane, a quantity of light totally reflected and propagated in transmissive member 16 is greater than in a surface-emitting panel provided with an organic EL element having the Lambertian distribution, and hence a quantity of light which is scattered and reflected by reflection member 20 provided to face non-light-emitting portion 40 and exits toward the front also increases.

Surface-emitting unit 1 according to the present embodiment can guide more light of light emitted from the organic EL element to a light exit surface of transmissive member 16 in the portion corresponding to the non-light-emitting portion and the periphery thereof. Therefore, a luminance in the front direction of that portion is improved, and hence non-uniformity in luminance is lessened and the non-light-emitting portion is more inconspicuous.

Therefore, by adopting the configuration of surface-emitting unit 1 according to the present embodiment, a surface-emitting unit achieving an improved front luminance of the portion corresponding to non-light-emitting portion 40 and the periphery thereof as compared with a conventional example can be obtained and a surface-emitting unit in which non-uniformity in luminance is lessened and a non-light-emitting portion is more inconspicuous can be obtained.

### Second Embodiment

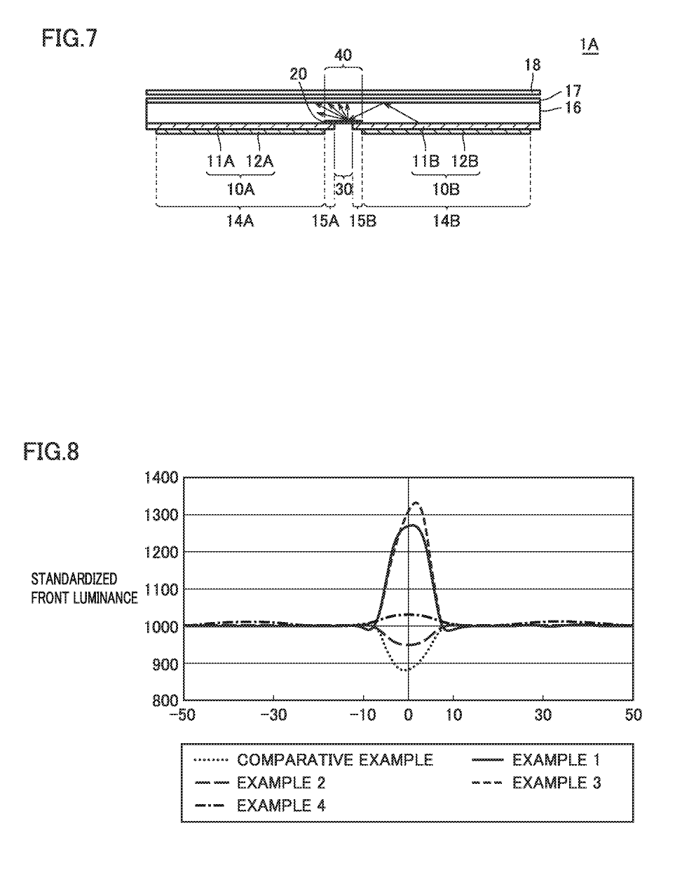

A surface-emitting unit 1A according to a second embodiment will be described with reference to FIG. 7. FIG. 7 is a cross-sectional view showing the surface-emitting unit in the second embodiment. A difference between surface-emitting unit 1A and surface-emitting unit 1 (see FIG. 2) will be described here. The configuration of surface-emitting unit 1A corresponds to the configuration of surface-emitting unit 1 to which an optical filter 17 and a scattering sheet 18 are added and it is otherwise the same as the configuration of surface-emitting unit 1.

Optical filter 17 is arranged in parallel to the surface of transmissive member 16 on a light exit side and provided between scattering sheet 18 and transmissive member 16. Optical filter 17 is optically in intimate contact with transmissive member 16. Optical filter 17 is desirably joined to the surface of transmissive member 16 on the light exit side with a transparent optical adhesive.

Optical filter 17 functions as a dimming member and decreases a quantity of light which exits from the light exit surface of transmissive member 16. Optical filter 17 decreases a quantity of light incident on optical filter 17 by a prescribed quantity and has the resultant light exit. Specifically, a pattern having an annular dimming region for decreasing a quantity of light is printed on optical filter 17 with ink-jet printing. This pattern adjusts a transmittance of optical filter 17.

Scattering sheet 18 functions as a scattering member, allows passage of light emitted from surface-emitting panels 10A to 10D as being scattered (diffused) to the outside, and is provided to face the light exit surface of transmissive member 16. Specifically, scattering sheet 18 is bonded to optical filter 17 with air being interposed between the scattering sheet and the surface of optical filter 17.

With such a configuration, when surface-emitting panel 10 is visually recognized from the front, a boundary between a region where a scattering and reflecting surface facing the non-light-emitting portion is formed and a light-emitting region can be more inconspicuous and a surface-emitting unit achieving lessening of non-uniformity in luminance can be realized. A scattering sheet which scatters light by making use of an internal scattering function with fine particles being contained or a scattering sheet which scatters light by making use of an interfacial reflection function with surface irregularities is available as scattering sheet 18.

Light generated by light-emitters 12A and 12B passes through transparent substrates 11A and 11B, is emitted from light-emitting surfaces 13A and 13B, and thereafter enters transmissive member 16. The light which enters the transmissive member passes through transmissive member 16, and exits toward scattering sheet 18 through optical filter 17 or exits toward scattering sheet 18 through optical filter 17 as being reflected and propagated in transmissive member 16.

The light distribution curve in the present embodiment also includes a portion satisfying the condition of L>cos θ, with a luminance on the front side along the optical axis extending in the direction of normal to the light-emitting surface being defined as 1 and L representing a luminance in a direction in which an angle formed with respect to the optical axis in the plane is θ.

The light distribution in the vertical plane shown with the light distribution curve in the present embodiment also means that angular dependency of light which exits from the light-emitting surface is different from the normal Lambertian distribution and particularly means that a quantity of light which exits in an oblique direction with respect to the front side is greater than a quantity of light which exits toward the front.

By employing surface-emitting panels 10A and 10B having such a light distribution in the vertical plane, more light of light emitted from surface-emitting panels 10A and 10B is totally reflected and propagated in transmissive member 16, so that a quantity of light which is scattered and reflected by reflection member 20 provided to face non-light-emitting portion 40 and exits toward the front also increases.

Since surface-emitting unit 1A according to the present embodiment can also guide more light of light emitted from the organic EL element to scattering sheet 18 in the portion corresponding to the non-light-emitting portion and the periphery thereof, a luminance in the front direction of that portion is improved.

In surface-emitting unit 1A according to the present embodiment, optical filter 17 can adjust a transmittance of light which exits toward the front, and light which enters scattering sheet 18 in the portion corresponding to non-light-emitting portion 40 and the periphery thereof is further scattered by scattering sheet 18 and emitted to the outside. Therefore, non-uniformity in luminance is further lessened and the non-light-emitting portion is more inconspicuous.

Therefore, with surface-emitting unit 1A in the present embodiment as well, a surface-emitting unit achieving an improved front luminance in the portion corresponding to non-light-emitting portion 40 and the periphery thereof as compared with a conventional example can be obtained and a surface-emitting unit in which non-uniformity in luminance is lessened and a non-light-emitting portion is more inconspicuous can be obtained.

### EXAMPLES

Results of simulation of a front luminance profile of surface-emitting units according to Examples 1 to 4 based on the embodiments described above will be described below. For comparison, results of simulation of a front luminance profile of a surface-emitting unit according to a Comparative Example not based on the embodiments described above will also be shown.

The surface-emitting units according to Examples 1 to 3 include the surface-emitting panels including the organic EL elements according to the first configuration example to the third configuration example described in the first embodiment described above, respectively.

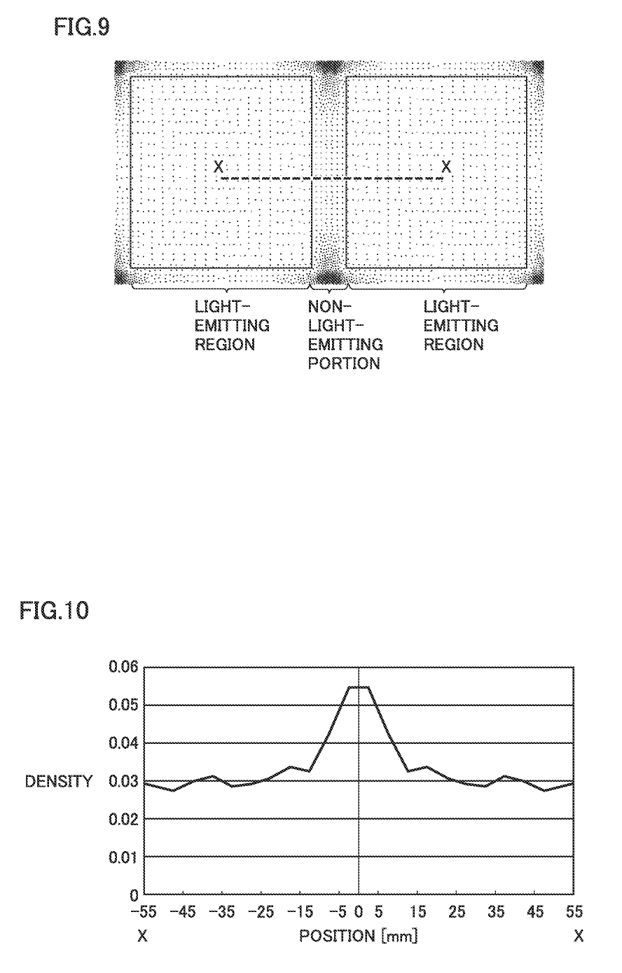

The surface-emitting unit according to Example 4 includes the surface-emitting panel including the organic EL element according to the first configuration example shown in FIG. 6, in the surface-emitting unit according to the second embodiment. The surface-emitting unit according to Example 4 includes an optical filter shown in FIGS. 9 and 10 which will be described later, as the optical filter described above.

In each of the surface-emitting units according to Examples 1 to 4 and Comparative Example, the surface-emitting panel has a width of 90 mm, the non-light-emitting portion (the non-light-emitting region and the gap) has a width of 10 mm, an acrylic plate as the transmissive member (having an index of refraction of 1.5) has a thickness of 3 mm, and a white reflection film is used for the reflection member. The optical filter in the surface-emitting unit according to Example 4 has a dimming region having a transmittance of approximately 70% and Haze of 90% or higher, in accordance with a density distribution.

FIG. 8 is a graph showing standardized front luminance profiles of the surface-emitting units according to Examples 1 to 4 and Comparative Example. FIG. 9 is a conceptual, partially enlarged view showing a distribution of a density of dimming regions of the optical filter in Example 4. FIG. 10 shows a density profile in a cross-section along the line X-X in FIG. 9. Positions (mm) on the abscissa shown in FIGS. 8 and 10 show that 0 mm represents the center of the non-light-emitting portion produced between two juxtaposed surface-emitting panels, ±5 mm represents positions where the non-light-emitting portion is present, and ±50 mm represents the substantial center of the surface-emitting panel. The standardized front luminance shown in FIG. 8 is standardized such that the center of the surface-emitting panel (the center of the light-emitting region) is defined to have a value of 1000.

Referring to FIG. 8, it can be confirmed that the standardized front luminance at the light-emitting surface of the surface-emitting unit in Comparative Example is low in a region corresponding to the non-light-emitting portion produced between two juxtaposed surface-emitting panels.

It can be seen that the surface-emitting units according to Examples 1 and 3 achieve a significantly improved front luminance as compared with the surface-emitting unit according to Comparative Example, in the region corresponding to the non-light-emitting portion. This is because, as shown in the light distribution shown in FIG. 5, there is much light emitted at an angle around a critical angle between the acrylic plate and air (42°) or light emitted at an angle exceeding the critical angle in the surface-emitting units according to Example 1 (corresponding to the first configuration example) and Example 3 (corresponding to the third configuration example).

Specifically, much of light emitted at an angle in the vicinity of the critical angle (for example, a critical angle ±10°) propagates as being reflected in the transmissive member and reaches the reflection member (the scattering and reflecting surface), and an angle of incidence of the light with respect to the scattering and reflecting surface is small (an angle formed with respect to the normal to the scattering and reflecting surface is small). Therefore, the light tends to be scattered toward the front. Accordingly, when the surface-emitting panel has such a light distribution that there is much light emitted at an angle around the critical angle, a luminance can efficiently be improved in the region corresponding to the non-light-emitting portion.

Since light emitted from a peripheral region of the surface-emitting panel (a region in the vicinity of the non-light-emitting portion) is small in number of times of reflection until the light propagates through the transmissive member and reaches the reflection member (the scattering and reflecting surface), a quantity of dimmed light is small. Therefore, with a light distribution as satisfying the condition of L>cos θ in particular in the peripheral region of the surface-emitting panel, a luminance can efficiently be improved in the region corresponding to the non-light-emitting portion.

It can be seen that the region corresponding to the non-light-emitting portion in the surface-emitting unit according to Example 2 achieves an improved front luminance as compared with the surface-emitting unit according to Comparative Example, although improvement is not as great as improvement in the surface-emitting units according to Examples 1 and 3. This is because light emitted at an angle around the critical angle between the acrylic plate and air (42°) or light emitted at an angle exceeding the critical angle in the surface-emitting unit according to Example 2 (corresponding to the second configuration example) is less than light in the surface-emitting units according to Examples 1 and 3, however, light emitted at the angle around the critical angle is more than light in the surface-emitting unit according to Comparative Example, as shown in the light distribution shown in FIG. 5.

It can be seen with reference to FIG. 8 that the front luminance of the region corresponding to the non-light-emitting portion in each of Examples 1 and 3 is higher than the front luminance of the region corresponding to the light-emitting region. In such a case, non-uniformity in luminance can be lessened by adjusting a transmittance of light which exits toward the front with the use of the optical filter as in Example 4. The optical filter used in Example 4 has a pattern with a plurality of dimming regions, and a distribution of light transmittance of this optical filter is adjusted by adjusting a position of arrangement and a size of the plurality of dimming regions.

As shown in FIGS. 9 and 10, it can be seen that the optical filter applied in Example 4 is higher in density of annular dimming regions (black points in FIG. 9) in the region facing the non-light-emitting portion than in the region facing the light-emitting region, in its surface. Namely, the optical filter has in its surface, such a distribution of light transmittance that a transmittance of light in the region facing the light-emitting region is higher than a transmittance of light in the region facing the non-light-emitting portion. The annular dimming region provided in the optical filter has a diameter of 0.6 mm.

As described above, the surface-emitting unit according to Example 4 includes the surface-emitting panel including the organic EL element according to the first configuration example as in Example 1. It can be seen with reference to FIG. 8 again that the surface-emitting unit according to Example 4 is lower in front luminance of the non-light-emitting portion than the surface-emitting unit according to Example 1, with a distribution of the front luminance as a whole being more uniform.

Thus, when the surface-emitting panel has in its surface, such a distribution of a luminance of a light source that a front luminance of a peripheral portion of the light-emitting region is higher than a front luminance in a central portion thereof, the optical filter is desirably configured as follows. Namely, the optical filter is configured to have such a distribution of light transmittance that, in the surface thereof, the region facing the light-emitting region is higher in transmittance than the region facing the non-light-emitting region (or the non-light-emitting portion). Then, a more uniform distribution of the front luminance can be realized.

Though the Example (Example 4) in which the optical filter is applied to the surface-emitting unit according to Example 1 is shown here, a more uniform distribution of the front luminance can be realized by applying the similarly configured optical filter also to the surface-emitting unit according to Example 3.

Though the front luminance can be more uniform by adjusting a thickness of a light-emitter, in consideration of production errors, control of errors is facilitated by applying an optical filter of which transmittance in its surface can be adjusted. Even when the front luminance of the non-light-emitting region (or the non-light-emitting portion) is high as in Examples 1 and 3, loss of a quantity of light can be lessened by making the front luminance uniform by decreasing a quantity of light in the region corresponding to the non-light-emitting region with the use of an optical filter, rather than by making the front luminance uniform by decreasing a quantity of light in the region corresponding to the light-emitting region greater in area than the non-light-emitting region.

As is understood also from the results of simulation, generally, such a distribution of a front luminance that a luminance in the front direction of a portion corresponding to a non-light-emitting portion and a periphery thereof is improved as compared with the conventional example is obtained with the configuration of the surface-emitting unit in the embodiments described above. It was thus confirmed that a surface-emitting unit in which non-uniformity in luminance was lessened and the non-light-emitting portion was more inconspicuous was obtained.

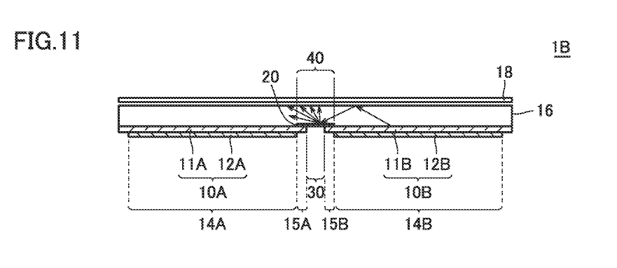

Though a configuration in which an optical filter and a scattering sheet are added to the surface-emitting unit according to the first embodiment is described as the configuration of the surface-emitting unit according to the second embodiment in the embodiments described above, a surface-emitting unit in which only scattering sheet 18 is added to surface-emitting unit 1 according to the first embodiment as shown in FIG. 11 may be employed as a surface-emitting unit according to another embodiment.

FIG. 11 is a cross-sectional view showing a surface-emitting unit 1B in another embodiment. The configuration of surface-emitting unit 1B corresponds to the configuration of surface-emitting unit 1 to which scattering sheet 18 is added, and it is otherwise the same as the configuration of surface-emitting unit 1. Specifically, in surface-emitting unit 1B, scattering sheet 18 is bonded to transmissive member 16 with air being interposed between the scattering sheet and the surface of transmissive member 16. Scattering sheet 18 may optically be in intimate contact with transmissive member 16 without air being interposed between the scattering sheet and the surface of transmissive member 16.

Surface-emitting unit 1B according to another embodiment can also realize a surface-emitting unit in which a luminance in the front direction of a portion corresponding to a non-light-emitting portion and a periphery thereof is improved.

In each embodiment described above, though a case that an integrated reflection member in a cross shape is arranged in a gap formed between adjacent surface-emitting panels so as to adapt to the shape of the gap has been exemplified and described, the reflection member may be formed from such four reflection members that sites each extending in a form of a rod are independently formed.

In each embodiment described above, though a case that the non-light-emitting portion and the reflection member are substantially equal to each other in width has been exemplified and described, the widths do not necessarily have to be equal to each other, and any one may be greater than the other.

In each embodiment described above, though a case that desired light distribution characteristics are obtained by adjusting a thickness of the electron transfer layer of the organic EL element has been exemplified, a method of obtaining desired light distribution characteristics is not limited thereto, and for example, another method such as modifying a film configuration of an organic EL element can naturally be applied. When a surface-emitting panel including a light source other than an organic EL element is employed as the surface-emitting panel as well, desired light distribution characteristics as described above can be obtained by variously adjusting a configuration of the light source.

In each embodiment described above, though a surface-emitting unit including four surface-emitting panels in array has been exemplified and described, the number or a layout of surface-emitting panels is not limited as such, and a surface-emitting unit in any configuration in which two or more surface-emitting panels are provided and the surface-emitting panels are disposed as being two-dimensionally adjacently disposed is applicable.

The surface-emitting unit to which the present embodiment is applied is not limited to lighting apparatuses in a narrow sense, which are used in applications of indoor and outdoor lighting, and the surface-emitting unit includes lighting apparatuses in a broad sense, which are provided, for example, in a display, a display device, or a signboard or an advertisement of an electronic display type.

Though a case that a scattering sheet is bonded to an optical filter with air being interposed between the scattering sheet and the surface of the optical filter is exemplified in the second embodiment described above, limitation thereto is not intended and a scattering sheet may optically be in intimate contact with an optical filter without air being interposed between the scattering sheet and the surface of the optical filter.

Though a case that the reflection member is formed from a reflection film or a white ink and a scattering and reflecting surface and a light-emitting surface are relatively flat has been described in each embodiment described above, limitation thereto is not intended and a scattering and reflecting surface may have an angle of inclination. Thus, a quantity of light which exits toward the front in the non-light-emitting portion increases and a luminance of the non-light-emitting portion can be improved.

A configuration in which a reflection member is provided in a portion of a transmissive member which faces a light-emitting surface has been exemplified in each embodiment described above. A reflecting and scattering element may be provided in the transmissive member, in a portion of the transmissive member which faces the light-emitting surface, so as to overlap with a non-light-emitting region when viewed from the front.

A semi-transmissive scattering element (for example, having a scattering transmittance of 50%) which allows passage of light as being scattered may be provided as a light scattering portion, on an exit surface side of the transmissive member so as to overlap with a non-light-emitting region when viewed from the front, instead of a reflection member which scatters and reflects light. By doing so as well, a surface-emitting unit in which a luminance in a front direction of a portion corresponding to a non-light-emitting portion and a periphery thereof is improved can be obtained.

The surface-emitting unit described above includes a plurality of surface-emitting panels which are disposed such that light-emitting surfaces are two-dimensionally aligned and emit light toward a front, a transmissive member which is arranged to face the light-emitting surfaces of adjacent surface-emitting panels and propagates light emitted from the surface-emitting panels as being reflected therein, and a light scattering portion which scatters the light propagated by the transmissive member toward the front.

The light-emitting surface of each of the plurality of surface-emitting panels has a light-emitting region which emits light and a non-light-emitting region which is located around an outer periphery of the light-emitting region and does not emit light. The light scattering portion is provided on the surface-emitting panel so as to overlap with the non-light-emitting region when viewed from the front. When a light distribution curve in a plane perpendicular to the light-emitting surface of light emitted from the surface-emitting panel is drawn for each of the plurality of surface-emitting panels, the surface-emitting unit has at least a portion where the light distribution curve satisfies a condition of L>cos θ, with a luminance on a front side along an axis extending in a direction of normal to the light-emitting surface being defined as 1 and L representing a luminance in a direction in which an angle formed with respect to the axis in the plane is θ.

Preferably, the angle θ in the portion in which the condition of L>cos θ is satisfied is an angle in the vicinity of a critical angle between the transmissive member and the outside.

Preferably, the light scattering portion is provided in a portion of the transmissive member which faces the light-emitting surface and formed from a reflection member which scatters and reflects some of light propagated by the transmissive member toward the front.

Preferably, the surface-emitting unit includes a scattering member which is provided to face a light exit surface of the transmissive member and scatters light emitted from the plurality of surface-emitting panels.

Preferably, the surface-emitting unit further includes a dimming member provided between the transmissive member and the scattering member. The dimming member has such a light transmittance distribution in a surface thereof that a transmittance of light in a region facing the light-emitting region is higher than a transmittance of light in a region facing the non-light-emitting region.

A luminance in the front direction of a portion corresponding to the non-light-emitting portion and a periphery thereof can be improved by adopting the configuration described above.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1, 1A, 1B surface-emitting unit; 10A, 10B, 10C, 10D surface-emitting panel; 11A, 11B, 11C, 11D transparent substrate; 12A, 12B, 12C, 12D light-emitter; 13A, 13B, 13C, 13D light-emitting surface; 14A, 14B, 14C, 14D light-emitting region; 15A, 15B, 15C, 15D non-light-emitting region; 16 transmissive member; 17 optical filter; 18 scattering sheet; 20 reflection member; 30 gap; 40 non-light-emitting portion; 110 transparent electrode layer; 120 organic electroluminescent layer; 121 light-emitting layer; 122 hole transfer layer; 123 electron transfer layer; and 130 reflection electrode layer.

1. A surface-emitting unit comprising:
a plurality of surface-emitting panels which are disposed such that light-emitting surfaces are two-dimensionally aligned and emit light toward a front;
a transmissive member which is arranged to face the light-emitting surfaces of adjacent surface-emitting panels and propagates light emitted from the surface-emitting panels as being reflected in the transmissive member; and
a light scattering portion which scatters the light propagated by the transmissive member toward the front,
the light-emitting surface of each of the plurality of surface-emitting panels having a light-emitting region which emits light and a non-light-emitting region which is located around an outer periphery of the light-emitting region and does not emit light,
the light scattering portion being provided on the surface-emitting panel so as to overlap with the non-light-emitting region when viewed from the front, and
when a light distribution curve in a plane perpendicular to the light-emitting surface of light emitted from the surface-emitting panel is drawn for each of the plurality of surface-emitting panels, the light distribution curve having at least a portion in which a condition of L>cos θ is satisfied, with a luminance on a front side along an axis extending in a direction of normal to the light-emitting surface being defined as 1 and L representing a luminance in a direction in which an angle formed with respect to the axis in the plane is θ.

2. The surface-emitting unit according to claim 1, wherein
the angle θ in the portion in which the condition of L>cos θ is satisfied is an angle near a critical angle between the transmissive member and outside.

3. The surface-emitting unit according to claim 1, wherein
the light scattering portion is provided in a portion of the transmissive member which faces the light-emitting surface and formed from a reflection member which scatters and reflects some of light propagated by the transmissive member toward the front.

4. The surface-emitting unit according to claim 1, the surface-emitting unit further comprising a scattering member which is provided to face a light exit surface of the transmissive member and scatters light emitted from the plurality of surface-emitting panels.

5. The surface-emitting unit according to claim 4, the surface-emitting unit further comprising a dimming member provided between the transmissive member and the scattering member, wherein
the dimming member has such a light transmittance distribution in a surface of the dimming member that a transmittance of light in a region facing the light-emitting region is higher than a transmittance of light in a region facing the non-light-emitting region.
